(19) United States
(12) Patent Application Publication
(10) Pub. No.: US 2025/0295044 A1
(43) Pub. Date: Sep. 18, 2025

(54) HAMMERHEAD BOTTOM ELECTRODE IN MEMORY DEVICES

(71) Applicant: Applied Materials, Inc., Santa Clara, CA (US)

(72) Inventors: Amirhasan Nourbakhsh, Albany, NY (US); Joseph F. Salfelder, Pleasant Valley, NY (US); Jason A Appell, Malta, NY (US); Jet Beng Tan, Albany, NY (US); Jee-Jay James Chen, Ballston Lake, NY (US)

(73) Assignee: Applied Materials, Inc., Santa Clara, CA (US)

(21) Appl. No.: 18/606,414

(22) Filed: Mar. 15, 2024

(51) Int. Cl. H10N 70/00; H10B 63/00; H10N 70/20

(52) U.S. Cl. CPC H10N 70/841; H10B 63/80; H10N 70/028; H10N 70/063; H10N 70/24; H10N 70/8265

(57) ABSTRACT

Forming planar resistive memory devices on metal vias that are planed level with the surrounding insulating material may transfer dishing or other surface imperfections in the surface of the metal vias throughout the layers of the memory cell and degrade the performance of the device. A bottom electrode having a “hammerhead” shape may be formed by leaving a top portion of the metal layer over the insulating layer instead of polishing down to the insulating layer. The top portion of the electrode may be oxidized to form the switching layer for the memory cell itself. This hammerhead electrode may have a substantially flat surface on which to form the layers of the planar memory cell, resulting in better memory performance and heat dissipation. When oxidized, the hammerhead electrode also eliminates the metal/metal-oxide interface between the bottom electrode and the switching material.

### TECHNICAL FIELD

The present technology relates to semiconductor systems, processes, and equipment. More specifically, the present technology relates to processes and systems for forming a bottom electrode in memory devices.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. For example, Resistive Random Access Memory (RRAM), also known as Resistive RAM or ReRAM, is a type of non-volatile memory technology that stores data by changing the resistance of a material. ReRAMs, store data as varying resistance levels within a material stack, typically consisting of metal oxide layers. The resistance levels represent binary states, with one state corresponding to a high resistance and the other to a low resistance. This binary state can be switched by applying a voltage across the material, causing it to change from a high-resistance state to a low-resistance state or vice versa. This ability to change resistance states enables RRAM to store data reliably and efficiently.

### SUMMARY

In some embodiments, a memory device may include a metal plug including a via surrounded by an insulating material, and a top portion that extends above the insulating material and extends laterally beyond a width of the via. The memory device may also include a memory cell formed on top of the metal plug.

In some embodiments, a memory device may include a metal plug that includes a via surrounded by an insulating material, and a top portion that extends above the insulating material at and extends laterally beyond a width of the via. The top portion of the metal plug may be oxidized to form a metal-oxide switching region for the memory device. The memory device may also include a top electrode formed on the top portion of the metal plug.

In some embodiments, a method of forming a memory device may include forming a metal layer, where the metal layer may fill a feature in an insulating layer to form the via, and the metal layer may extend above a top surface of the insulating layer. The method may also include partially removing a portion of the metal layer, where a remaining portion of the metal layer continues to cover the insulating layer. The method may additionally include forming one or more layers for a memory cell on or in the remaining portion of the metal layer. The method may further include performing an etch to form the memory device over the via, where the etch may extend below the top surface of the insulating layer.

In any embodiments, any and all of the following features may be implemented in any combination and without limitation. The via may have a height of between about 50 nm and about 150 nm, and the via may have a width of between about 50 nm and about 150 nm. The top portion may extends laterally beyond the width of the via by between about 50 nm and about 150 nm. A bottom surface of the via may be electrically coupled to an underlying metal layer in a Back End Of Line (BEOL) portion of an integrated circuit. The memory cell may include a resistive random-access memory (ReRAM) cell comprising a switching layer between a bottom electrode and a top electrode. The bottom electrode of the memory cell may extend along an entire upper surface of the top portion of the metal plug. The via may include first angled sidewalls that are angled in a first direction, and the top portion of the metal plug may include second angled sidewalls that are angled in a second direction. The metal plug may be free of an interface between the via and the top portion of the metal plug, and the metal-oxide switching region may form a continuous gradient of oxidized material in the top portion of the metal plug. The via may include copper, tantalum, or titanium, and the top portion of the metal plug may include copper oxide, tantalum oxide, or titanium oxide. The top portion of the metal plug may have a height of between about 5 nm and about 50 nm. The memory device may be free of a bottom electrode between the metal-oxide switching region and the via. The etch to form the memory device may include a first etch process configured to stop at the remaining portion of the metal layer. The etch to form the memory device may include a second etch process configured to etch through the remaining portion of the metal layer and into the insulating material. The remaining portion of the metal layer may form a substantially flat surface free of dishing over the via from a Chemical Mechanical Polishing (CMP) process. Forming the one or more layers for a memory cell on or in the metal layer may include oxidizing a top portion of the metal layer to form a metal-oxide switching region for the memory device, where the memory device may be free of a bottom electrode between the metal-oxide switching region and the via; and forming a top electrode on the top portion of the metal layer. Forming the one or more layers for a memory cell on or in the metal layer may include forming a bottom electrode layer on the remaining portion of the metal layer; forming a metal-oxide switching layer on the bottom electrode layer; and forming a top electrode layer on the metal-oxide switching layer. Performing the etch to form the memory device over the via may include forming a metal plug including the via and a top portion of the metal plug that extends above the insulating material and extends laterally beyond the width of the via. Performing the etch to form the memory device over the via may include forming a metal plug having a hammerhead shape.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components.

In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIGS. 2A-2E illustrate a process for forming a memory device, according to some embodiments.

FIG. 3 illustrates a flowchart of a method for forming a memory device, according to some embodiments.

FIGS. 4A-4D illustrate a process for forming a memory device with a hammerhead electrode, according to some embodiments.

FIGS. 5A-5D illustrate a process for forming a memory device with an oxidized hammerhead electrode, according to some embodiments.

FIG. 6 illustrates a photograph of an example of a hammerhead electrode, according to some embodiments.

### DETAILED DESCRIPTION

Forming planar resistive memory devices on metal vias that are planed level with the surrounding insulating material may transfer dishing or other surface imperfections in the surface of the metal vias throughout the layers of the memory cell and degrade the performance of the device. A bottom electrode having a “hammerhead” shape may be formed by leaving a top portion of the metal layer over the insulating layer instead of polishing down to the insulating layer. The top portion of the electrode may be oxidized to form the switching layer for the memory cell itself. This hammerhead electrode may have a substantially flat surface on which to form the layers of the planar memory cell, resulting in better memory performance and heat dissipation. When oxidized, the hammerhead electrode also eliminates the metal/metal-oxide interface between the bottom electrode and the switching material.

Emerging nonvolatile memories, such as resistive random-access memories (ReRAMs) are becoming attractive platforms for embedded applications. For example, several high-performance memories embedded in copper-based back end of line (BEOL) layers have been demonstrated for various applications, including artificial intelligence, image processing, pattern recognition, and so forth. Typically, these types of memory structures have used planar cells. However, the performance of planar cells utilizing ultrathin films is extremely sensitive to the planarity of the top and bottom electrodes, which may have a significant impact on memory device performance, variability, and yield loss.

Specifically, memory arrays may be fabricated by forming ReRAM memory cells with planar memory elements. For example, the ReRAM cell may be formed as a capacitor between two metal layers in the BEOL stage of processing. Stated another way, the memory cell comprises a planar element between two metal plugs. The metal plugs may be formed from any conductive material, such as copper, tungsten, cobalt, and so forth. The memory cell may be placed on a bottom metal plug that has been formed into an oxide layer to connect the memory cell's bottom electrode to an underlying interconnect layer (e.g., M3, M4, etc.). The plug may be formed by etching a feature or hole in the oxide layer. The feature may then be filled with metal and planarized using a chemical-mechanical polishing (CMP) process. Unfortunately, this process invariably leaves a certain amount of dishing or gouging in the metal via, which is caused by the CMP process. These surface irregularities in the via adversely affect the planarity of the cell and the bottom electrode formed thereon for the memory element. Consequently, this may cause electric field nonuniformity within the cell dielectric, along with other variations in performance.

The embodiments described herein solve these and other technical problems by using a hammerhead bottom electrode specifically configured to reduce nonuniformity within the ReRAM itself. For example, the hammerhead bottom electrode may include a metal plug (e.g., tungsten, nickel, cobalt, copper, etc.) where the upper part of the metal plug protrudes above the surface of the oxide layer, forming a flat bottom electrode for the ReRAM bit cell. In addition to improving the bottom electrode planarity in the memory array, this process also eliminates the need to polish three different materials as required by previous solutions. For example, existing techniques polish the bulk metal material, the TaN/TiN liner, and the surrounding oxide layer. In contrast, these embodiments only need to remove the bulk metal material. These techniques also are insensitive to feature pattern size and pattern density. In some embodiments, the hammerhead bottom electrode may be used to form a seamless metal/metal-oxide junction (e.g., tungsten/tungsten oxide) by partially oxidizing the metal layer using an O₂/O₃ plasma. Metal oxides such as titanium oxide exhibit improved characteristics as resistance switching materials. This seamless metal/metal-oxide junction where the metal acts as the bottom electrode and the metal oxide as an active memory layer is immune to undesired defects and traps at the metal/oxide interface, which represents a significant advantage over deposited bilayer stacks used in previous designs.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

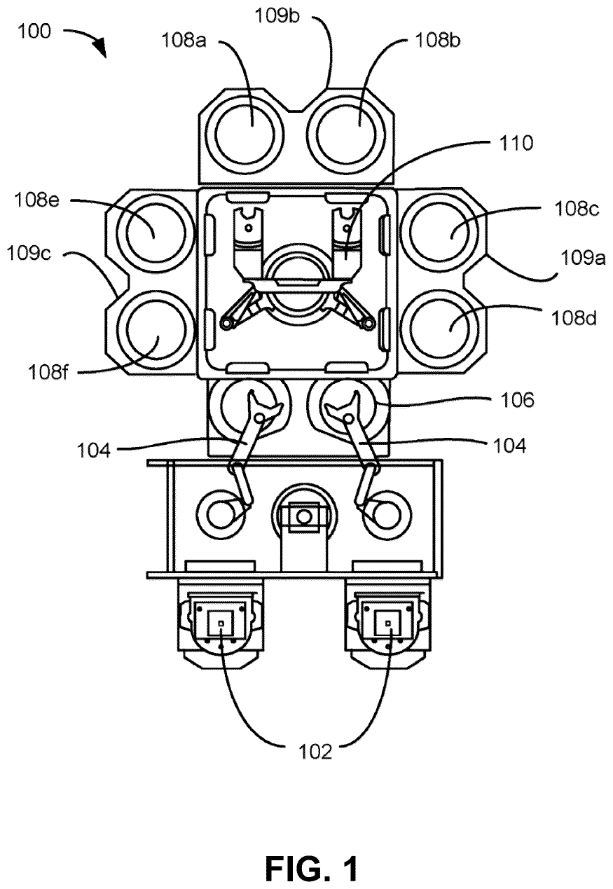

FIG. 1 shows a top plan view of one embodiment of a processing system 100 of deposition, etching, polishing, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The system 100, or more specifically chambers incorporated into system 100 or other processing systems, may be used to produce structures according to some embodiments of the present technology. For example, the system 100 may be used to perform deposition processes, chemical mechanical polishing (CMP) processes, etch processes, and so forth to form a memory device or an array of memory devices, including ReRAM devices. Although a ReRAM memory cell is used as an example in this disclosure, the hammerhead bottom electrode described below may also be incorporated into any other memory technology to improve performance and reduce the device variability. For example, this hammerhead bottom electrode may also be used in FRAM devices, MRAM devices, and so forth.

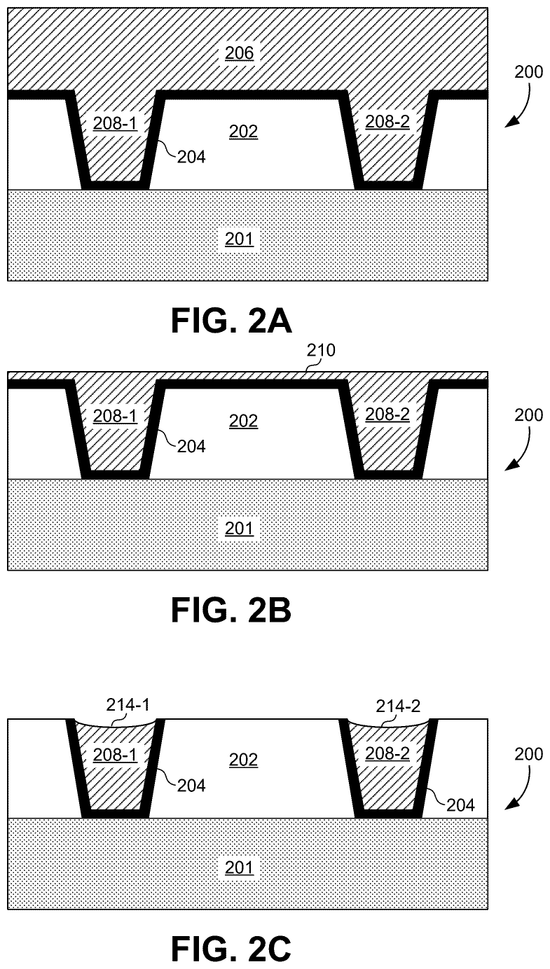

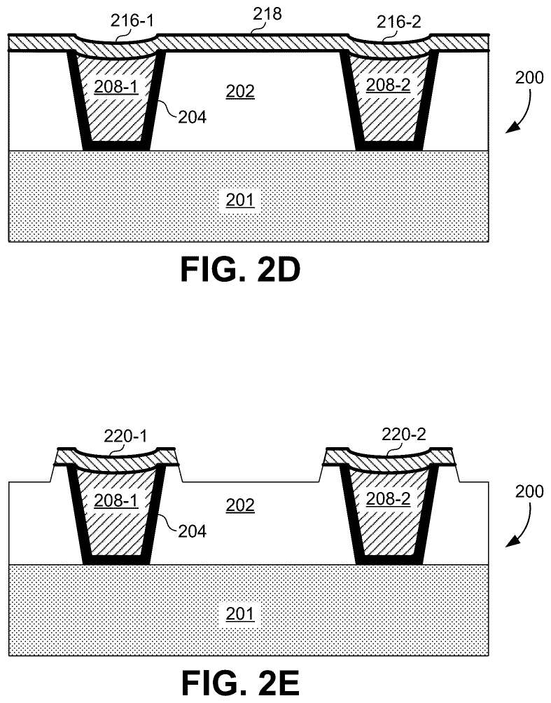

FIGS. 2A-2E illustrate a process for forming a memory device, according to some embodiments. As shown below, this methodology uses a CMP process to remove the metal layer down to the oxide or insulating layer. This results in surface imperfections that may be propagated to the other layers of the memory cell. This in turn may cause early switching and other nonuniformities in the operation of the memory device.

FIG. 2A illustrates the formation of two metal plugs 208 in an insulating layer 202 that are used to interface with individual memory cells. The insulating layer 202 may be formed on top of a metal layer 201. For example, in a BEOL process, the metal layer 201 may represent a BEOL metal layer, such as M3, M4, etc. The insulating layer 202 may be formed of an oxide (e.g., silicon oxide) or any other electrical insulator. Features or holes may be formed in the insulating layer 202 to expose the underlying metal layer 201. These features may be filled with the metal layer 206 to form the metal plugs 208 that may act as vias or electrical interfaces between the metal layer 201 and the bottom electrode of the memory cell.

Before forming the metal plugs 208, a liner 204 may be formed conformally over the insulating layer 202. In some embodiments, the liner 204 may include a bilayer liner. A first layer in the liner may include a material such as tantalum nitride to isolate the metal layer 201 from the metal plugs 208. For example, when different metals are used for the metal layer 201 and the metal plugs 208 (e.g., tungsten and copper) the tantalum nitride layer may prevent migration between these two metals. Additionally, a second layer of the liner 204 may include a titanium nitride layer. These layers of the liner 204 may be formed using a Chemical Vapor Deposition (CVD) process or any other suitable process. In some embodiments, the liner 204 may extend conformally along the sidewalls and bottoms of the features or holes in the insulating layer 202. The liner 204 may also conformally cover a top surface of the insulating layer 202 between the features as illustrated in FIG. 2A.

After the liner 204 is formed, a metal layer 206 may be formed over the insulating layer 202. For example, a conductive metal (e.g., tantalum, titanium, tungsten, copper, etc.) may be deposited on the insulating layer 202. The metal layer 206 may fill each of the features to form the metal plugs 208. Additionally, the metal layer 206 may cover a top surface of the insulating layer 202. For example, the metal layer 206 may extend more than 100 nm above the top surface of the insulating layer 202.

FIG. 2B illustrates the bulk removal of a portion of the metal layer 206, according to some embodiments. For example, a CMP process may be used to remove a large portion of the metal layer 206, thereby leaving a remaining portion of the metal layer 210. The CMP process may be configured to rapidly remove the bulk of the metal layer 206, and may stop before the liner 204 and/or the top surface of the insulating layer 202 are exposed. The remaining portion of the metal layer 210 may be less than 100 nm thick, less than 50 nm thick, less than 25 nm thick, and/or other thicknesses according to different embodiments. This process may remove more than 50% of the metal layer 206, more than 60% of the metal layer 206, more than 70% of the metal layer 206, more than 80% of the metal layer 206, more than 90% of the metal layer 206, and/or more than 90% of the metal layer 206.

FIG. 2C illustrates the removal of the remaining portion of the metal layer 210, according to some embodiments. For example, a CMP process may be used to remove the remaining portion of the metal layer 210. In some embodiments, this removal process may also remove the portion of the liner 204 that covers the top surface of the insulating layer 202. The CMP process may be slower or more tightly controlled than the CMP process used to remove the bulk of the metal layer 206 described above. The complete removal of the remaining portion of the metal layer 210 (and the liner 204) on top of the insulating layer 202 is typically performed at this stage to isolate the metal plugs 208 from each other.

In some embodiments, this CMP process may use endpoint detection techniques to determine when the remaining portion of the metal layer 210 has been removed. The CMP process may detect when the top surface of the insulating layer 202 has been exposed. As illustrated in FIG. 2C, the CMP process used to remove the remaining portion of the metal layer 210 may leave behind surface irregularities, particularly in the metal plugs 208. For example, the CMP process may leave behind “cupping” or “dishing” abnormalities 214 in the metal plugs 208. The surface irregularities may be primarily caused by the CMP process polishing multiple materials once the remaining portion of the metal layer 210 is removed. For example, dishing may occur when the CMP process simultaneously polishes the tops of the metal plugs 208 and the top surface of the insulating layer 202. These abnormalities 214 may be significant, especially in areas having a high feature density.

FIG. 2D illustrates the formation of the memory cells 216 over the metal plugs 208, according to some embodiments. The memory cells 216 may be plainer devices that are formed by multiple layers 218. For example, the memory cells 216 may include a metal layer acting as part of a bottom electrode, a switching material to implement the memory function, and another metal layer acting as part of a top electrode for the memory cell. The switching material may include different materials depending on the memory type. For example, a ReRAM device may include a metal-oxide material as the switching material. These layers 218 may be formed on top of the metal plugs, and these layers 218 may cover the metal plugs 208 as well as the insulating layer 202.

FIG. 2E illustrates the formation of individual memory cells 220, according to some embodiments. An etch process may be used to isolate the individual memory cells 220 from each other and position these individual memory cells 220 over the corresponding metal plugs 208. For example, a mask pattern may be formed over the layers 218 of the memory cells, and an etch process may be performed to remove the layers 218 between the metal plugs 208. In some embodiments, the etch process may completely etch through the layers 218 of the memory cell (e.g., through the top and bottom electrode materials and the switching material). The etch process may also etch down into the insulating layer 202. This process forms and isolates the individual memory cells 220 from each other. Note that the bottom electrodes of the memory cells 220 are conductively coupled to the metal plugs 208, which in turn are conductively coupled to the metal layer 201. Although not shown, the individual memory cells 220 may be part of a larger memory array formed on the substrate 200. Additionally, the metal layer 201 may include circuitry and routed metal lines that provide individual connections to each of the metal plugs 208.

Note that the topology of the surface irregularities (e.g., the dishing) in the metal plugs 208 is transferred to the layers of the individual memory cells 220 when the memory cells 220 are formed over the metal plugs 280. These irregularities affect the performance of the individual memory cells 220 and may affect the yield of the substrate 200 overall. Additionally, the top surface of the metal plugs 208 only interfaces with a portion of the bottom electrode of the individual memory cells 220. For example, the sides of the individual memory cells 220 overhang the outer diameter of the metal plugs 208. this tends to concentrate current flow and heat into the center portion of the individual memory cells 220 rather than distributing the current/heat throughout the bottom electrode.

The embodiments described herein solve these problems of surface irregularities on the metal plugs 208 as well as the concentration of current/heat in the center of the bottom electrode. Specifically, these embodiments form a metal plug having a “hammerhead” shape that provides a flat surface for the layers of the memory cell and that interfaces with the entire surface area of the bottom electrode.

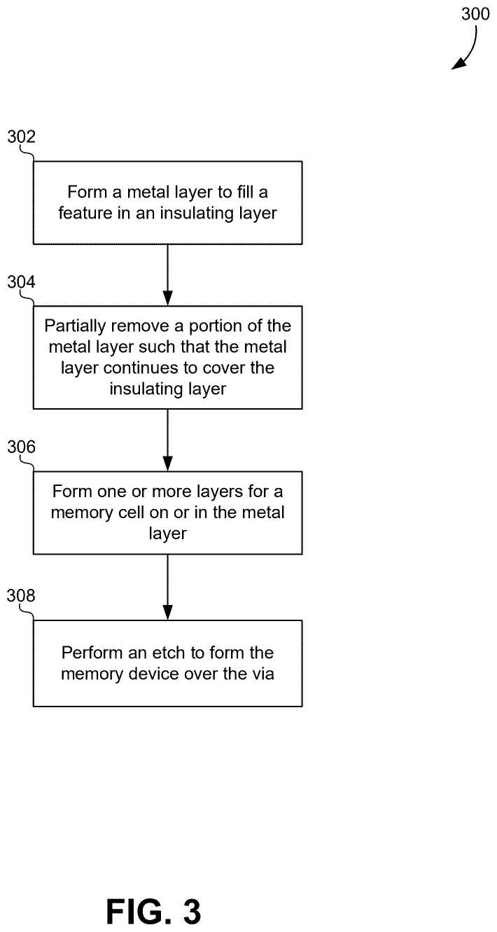

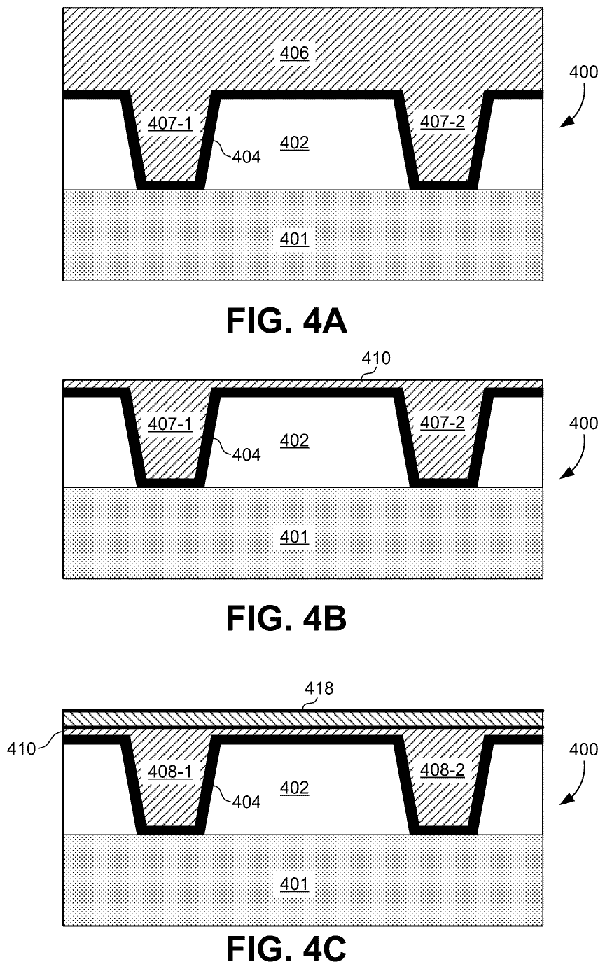

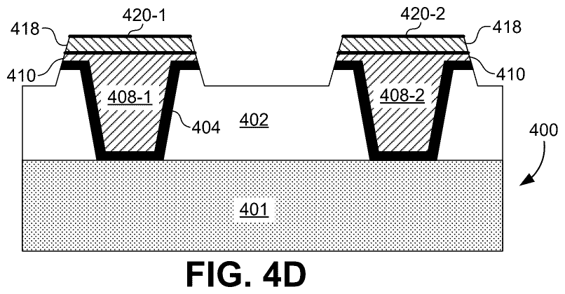

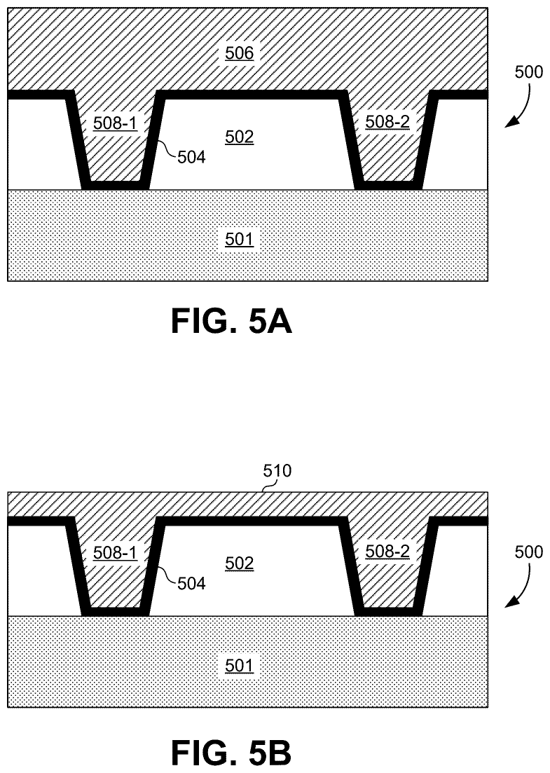

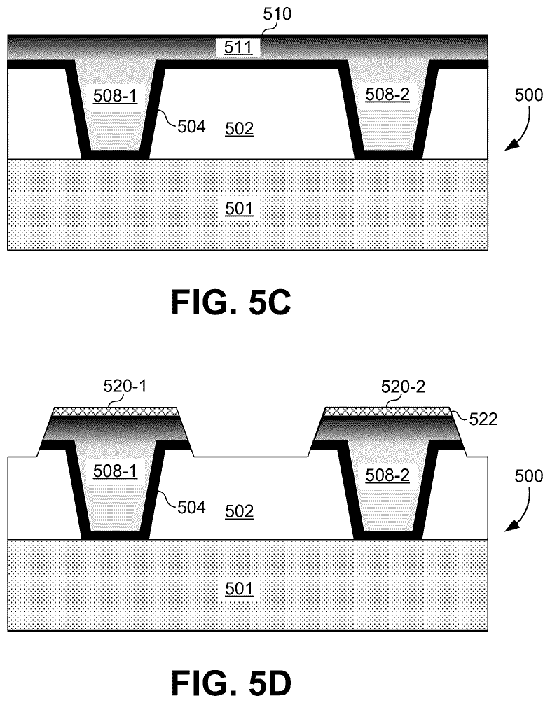

FIG. 3 illustrates a flowchart of a method 300 for forming a memory device, according to some embodiments. The memory device may include a metal plug that includes a via or pillar through the surrounding insulating material, as well as a top portion that extends above an insulating material and that extends laterally beyond the width of the via. FIGS. 4A-D and FIGS. 5A-D illustrate example structures that may be formed using this method 300. However, the structures illustrated in these figures are provided only by way of example and are not meant to be limiting.

The method 300 may include forming a metal layer (302). FIG. 4A illustrates a structure 400 with a metal layer 406 that fills features in insulating layer 402. The filled areas of these features may form vias 407. The metal layer 406 may extend above a top surface of the insulating layer 402. The structure 400 may also include a liner 404, such as the bilayer liner described above. The vias 407 may extend down to an underlying metal layer 401. Note that FIG. 4A is similar to FIG. 2A described above. Therefore any of the features described in relation to FIG. 2A may also be applicable to FIG. 4A.

The method 300 may also include partially removing a portion of the metal layer 406 (304). As described above in relation to FIG. 2B, a CMP process may be used to partially remove a portion of the metal layer 406. FIG. 4B illustrates the removal of a portion of the metal layer 406. A remaining portion of the metal layer 410 may continue to cover the insulating layer 402. In contrast to the process described above in FIG. 2C, some embodiments may leave the remaining portion of the metal layer 410 over the insulating layer 402. The CMP process may leave behind a substantially flat surface that is free of dishing over the vias 407 since the CMP process only polishes the metal layer 406. For example, since the CMP process is performed over a uniform layer of the metal material and does not need to expose the insulating layer 402 and/or the liner 404, the CMP processes does not need to simultaneously polish two materials with a different surface hardness.

The method may include forming one or more layers for a memory cell on or in the remaining portion of the metal layer 410 (306). FIG. 4C illustrates the formation of the layers 418 for the memory cell. For example, forming the layers 418 may include forming a bottom electrode layer over the remaining portion of the metal layer 410, forming a metal-oxide switching layer on the bottom electrode layer, and forming a top electrode layer on the metal-oxide switching layer. In some embodiments, the formation of a separate bottom electrode layer may be omitted, and the top of the metal plug may act as the bottom electrode entirely. An alternate method of forming a layer for the memory cell is described below in FIG. 5C where the remaining portion of the metal layer 410 is oxidized to form a metal-oxide switching layer. Note that the layers 418 for the memory cell are formed on top of the substantially flat surface of the remaining portion of the metal layer 410. This substantially flat topology is thus transferred to each of the layers 418 of the memory cell thereby making these layers 418 also substantially flat. This effectively prevents the irregularities that were previously present over the metal plugs 408 from causing corresponding irregularities in the memory cell.

The method may further include performing an etch to form memory devices over the vias (308). FIG. 4D illustrates how the etch process can form a metal plug having a hammerhead shape, according to some embodiments. The etch process may include multiple etch processes. For example, a first etch process may be configured to etch through the layers 418 of the memory cell and stop at the remaining portion of the metal layer 410. A second etch process may be configured to etch through the remaining portion of the metal layer 410 and into the insulating layer 402. This etch process isolates the metal plugs 408 and forms the individual memory cells 420.

For example, the via portion of the metal plugs 408 may have a height of between about 50 nm and about 75 nm, between about 75 nm and about 100 nm, between about 100 nm and about 125 nm, between about 125 nm and about 150 nm, between about 150 nm and about 175 nm, between about 175 nm and about 200 nm, and so forth. The height of the via may include any combination of ranges described above (e.g., between about 50 nm and about 150 nm). The height of the via may also include any single value included in any combination of ranges described above (e.g., about 100 nm).

For example, the via may have a width of between about 50 nm and about 75 nm, between about 75 nm and about 100 nm, between about 100 nm and about 125 nm, between about 125 nm and about 150 nm, between about 150 nm and about 175 nm, between about 175 nm and about 200 nm, and so forth. The width of the via may include any combination of ranges described above (e.g., between about 50 nm and about 150 nm). The width of the via may also include any single value included in any combination of ranges described above (e.g., about 100 nm).

The hammerhead shape of the metal plugs 408 may include both the via portion running vertically through the insulating layer 402 and a top portion of the metal plugs 408 that stands above the insulating material and extends laterally beyond a width of the via portion. For example, the overhang, or amount by which the top portion of the metal plug extends laterally beyond the width of the via, may be between about 10 nm and about 20 nm, between about 20 nm and about 30 nm, between about 30 nm and about 40 nm, between about 40 nm and about 50 nm, between about 50 nm and about 60 nm, between about 60 nm and about 70 nm, between about 70 nm and about 80 nm, between about 80 nm and about 90 nm, between about 90 nm and about 100 nm, and so forth. The overhang of the top portion of the metal plug may include any combination of ranges described above (e.g., between about 25 nm and about 50 nm). The width of the via may also include any single value included in any combination of ranges described above (e.g., about 75 nm).

The length of the overhang may also be measured relative to a width or Critical Dimension (CD) of the via. For example, the overhang may be between about 10% and about 20% of the CD of the via, between about 20% and about 30%, between about 30% and about 40%, between about 40% and about 50%, between about 50% and about 60%, between about 60% and about 70%, and so forth. The overhang of the top portion of the metal plug may include any combination of ranges described above (e.g., between about 30% and about 50%). The width of the via may also include any single value included in any combination of ranges described above (e.g., about 45%).

In some embodiments, the length of the overhang may be determined by the height of the remaining portion of the metal layer 410 left behind after the CMP process removes the bulk of the metal layer 406. For example, the etch process may leave behind angled sidewalls as depicted in FIG. 4D. The size of the top electrode of the memory cells 420 may be determined by size of the corresponding opening in the mask layer of the etch process. Consequently, the width of the bottom electrode, the overall width of the top portion of the metal plug, and thus the length of the overhang may be determined by the overall height of the device. In other words, as the height of the device increases, the angle of the etch will leave a wider base area of the memory device. The angle of the sidewalls of the overhang may be between about 3° and about 5°, between about 5° and about 8°, between about 8° and about 10°, between about 10° and about 12°, between about 12° and about 15°, between about 15° and about 20°, between about 20° and about 25°, between about 25° and about 35°, and so forth. In some embodiments, the overall height of the memory cell may be limited to the process height between metal layers in the BEOL process. For example, the height of the top portion of the metal plugs 408 and the layers 418 of the memory device may be limited to a standard height, such as 200 nm. This may thereby limit the width of the top portion of the metal plugs 408.

As illustrated by FIG. 4D, the sidewalls of the via portion of the metal plugs 408 may also have angled sidewalls. The angle of the sidewalls of the via portion may be angled in a first direction that is approximately opposite of a direction of the angle of the top portion of the metal plugs 408. For example, when measured from a vertical 90° line that is orthogonal to the substrate or the underlying metal layer 401, the angle of the sidewalls of the via may be between about 5° and about 30°, and the angle of the sidewalls of the top portion of the metal plugs 408 may be between about −5° and about −30°.

As illustrated in FIG. 4D, the top portion of the metal plugs 408 may now be in complete contact with the memory cell. For example, the top portion of the metal plugs 408 may be conductively coupled to an entire bottom surface of a bottom electrode (if present) in the layers 418 of the memory cell. This may allow the current to be distributed more evenly across the bottom electrode and may dissipate heat more effectively than previous designs.

Turning back to FIG. 3, the formation of the one or more layers for the memory cell may take place on top of the metal layer as described above. Alternatively, some embodiments may form the one or more layers for the memory cell in the metal layer itself (306). For example, FIG. 5A illustrates a structure 500 with a metal layer 506 that fills features in insulating layer 502. FIG. 5A is similar to FIG. 2A and FIG. 4A described above. Therefore any of the description in relation to FIG. 2A and FIG. 4A may also be applicable to FIG. 5A. As described above, a CMP process may be used to partially remove a portion of the metal layer 506. FIG. 5B illustrates the removal of a portion of the metal layer 506. A remaining portion of the metal layer 510 may continue to cover the insulating layer 502 to form a substantially flat surface.

FIG. 5C illustrates the formation of a switching layer for the memory cell in the remaining portion of the metal layer 510. For example, an oxidation process may be performed on the structure 500 using an O₂/O₃ plasma. This may cause a top portion of the metal material of the metal layer to become a metal-oxide material. For example, when titanium is used as the remaining portion of the metal layer 510, the oxidation process may form a titanium-oxide to act as a switching material in the memory cell.

In this configuration, the oxidized portion 511 of the metal layer 510 may act as the switching region or layer of the memory cell, and the un-oxidized portion of the metal layer 510 may act as a bottom electrode for the memory cell. In some embodiments, the oxidation process may result in a gradient of oxidation in the top portion of the remaining metal layer 510. This gradient may be represented as a continuous decrease in a concentration of the metal-oxide material until the metal material is free of oxidation at a certain depth. Therefore, the memory cell may be free of a discrete interface between the metal-oxide and the metal material that would normally be present between the switching material and the bottom electrode. This seamless metal/metal-oxide junction where the metal acts as the bottom electrode and the metal oxide acts as an active memory layer is immune to the undesired defects and traps that would otherwise be present at the metal/oxide interface. This represents a significant advantage over deposited bilayer stacks used in other designs.

FIG. 5D illustrates the formation of a top electrode 522 and the results of the etch process to form the individual memory elements 520. The top electrode 522 may formed using a similar process as described above in FIGS. 4A-D. The etch process may form the individual memory elements 520 as also described above in FIG. 4D.

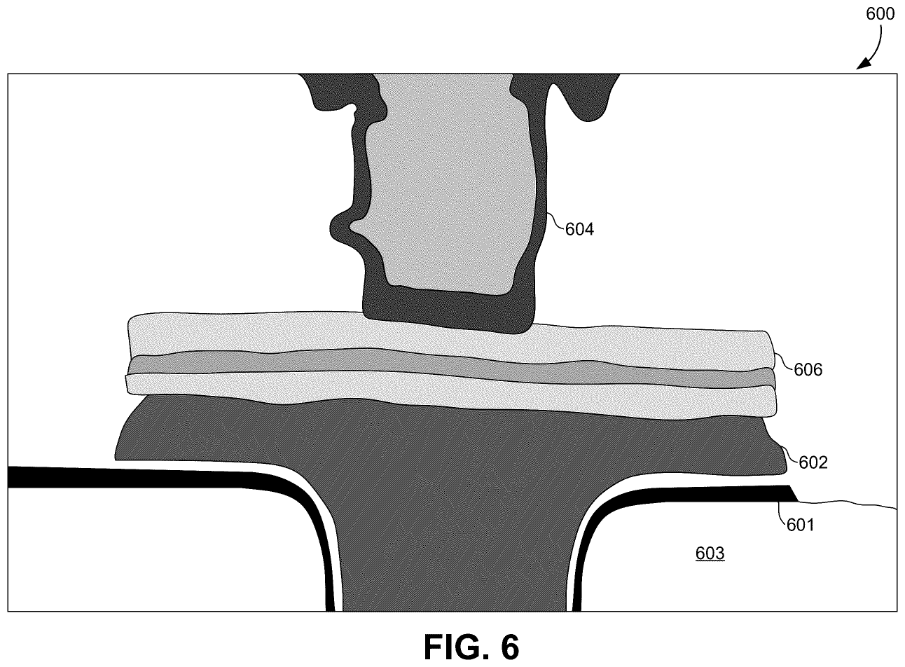

FIG. 6 illustrates a photograph of an example of a hammerhead electrode, according to some embodiments. This example shows a hammerhead electrode 608 with a vertical via and a top portion that extends above the insulating material 603 and extends laterally, or overhangs, beyond a width of the via. The overhanging portion 602 illustrates the angled sidewalls and a relative height of the overhanging portion 602 relative to the rest of the memory device. FIG. 6 also illustrates the bilayer liner 601 that may be present in some embodiments.

The layers 606 of the memory device are also illustrated. In this example, separate layers are present for the bottom electrode, the switching material, and the top electrode in the layers 606 of the memory device. As described above, some embodiments may omit the layer for the bottom electrode and/or form the switching material in the overhanging portion 602 of the hammerhead device. A second via 604 is shown making electrical contact with the top electrode of the memory device and thereby connect the memory device to subsequent metal layers and interconnects.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups. The terms “approximately,” “about,” and/or “substantially,” may refer to a nominal dimension or measurement that deviates by less than 10% of the stated value.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A memory device comprising:
a metal plug comprising a via surrounded by an insulating material, and a top portion that extends above the insulating material and extends laterally beyond a width of the via; and
a memory cell formed on top of the metal plug.

2. The memory device of claim 1, wherein the via has a height of between about 50 nm and about 150 nm, and the via has a width of between about 50 nm and about 150 nm.

3. The memory device of claim 1, wherein the top portion extends laterally beyond the width of the via by between about 50 nm and about 150 nm.

4. The memory device of claim 1, wherein a bottom surface of the via is electrically coupled to an underlying metal layer in a Back End Of Line (BEOL) portion of an integrated circuit.

5. The memory device of claim 1, wherein the memory cell comprises a resistive random-access memory (ReRAM) cell comprising a switching layer between a bottom electrode and a top electrode.

6. The memory device of claim 5, wherein the bottom electrode of the memory cell extends along an entire upper surface of the top portion of the metal plug.

7. The memory device of claim 1, wherein the via comprises first angled sidewalls that are angled in a first direction, and the top portion of the metal plug comprises second angled sidewalls that are angled in a second direction.

8. A memory device comprising:
a metal plug comprising a via surrounded by an insulating material, and a top portion that extends above the insulating material at and extends laterally beyond a width of the via, wherein the top portion of the metal plug is oxidized to form a metal-oxide switching region for the memory device; and
a top electrode formed on the top portion of the metal plug.

9. The memory device of claim 8, wherein the metal plug is free of an interface between the via and the top portion of the metal plug, and the metal-oxide switching region forms a continuous gradient of oxidized material in the top portion of the metal plug.

10. The memory device of claim 8, wherein the via comprises copper, tantalum, or titanium, and the top portion of the metal plug comprises copper oxide, tantalum oxide, or titanium oxide.

11. The memory device of claim 8, wherein the top portion of the metal plug has a height of between about 5 nm and about 50 nm.

12. The memory device of claim 8, wherein the memory device is free of a bottom electrode between the metal-oxide switching region and the via.

13. A method of forming a memory device, the method comprising:
forming a metal layer, wherein the metal layer fills a feature in an insulating layer to form the via, and the metal layer extends above a top surface of the insulating layer;
partially removing a portion of the metal layer, wherein a remaining portion of the metal layer continues to cover the insulating layer;
forming one or more layers for a memory cell on or in the remaining portion of the metal layer; and
performing an etch to form the memory device over the via, wherein the etch extends below the top surface of the insulating layer.

14. The method of claim 13, wherein the etch to form the memory device comprises a first etch process configured to stop at the remaining portion of the metal layer.

15. The method of claim 14, wherein the etch to form the memory device comprises a second etch process configured to etch through the remaining portion of the metal layer and into the insulating material.

16. The method of claim 13, wherein the remaining portion of the metal layer forms a substantially flat surface free of dishing over the via from a Chemical Mechanical Polishing (CMP) process.

17. The method of claim 13, wherein forming the one or more layers for a memory cell on or in the metal layer comprises:
oxidizing a top portion of the metal layer to form a metal-oxide switching region for the memory device, wherein the memory device is free of a bottom electrode between the metal-oxide switching region and the via; and
forming a top electrode on the top portion of the metal layer.

18. The method of claim 13, wherein forming the one or more layers for a memory cell on or in the metal layer comprises:
forming a bottom electrode layer on the remaining portion of the metal layer;
forming a metal-oxide switching layer on the bottom electrode layer; and
forming a top electrode layer on the metal-oxide switching layer.

19. The method of claim 13, wherein performing the etch to form the memory device over the via comprises forming a metal plug comprising the via and a top portion of the metal plug that extends above the insulating material and extends laterally beyond the width of the via.

20. The method of claim 13, wherein performing the etch to form the memory device over the via comprises forming a metal plug having a hammerhead shape.
